(19) United States
(12) Patent Application Publication
(10) Pub. No.: US 2017/0092640 A1
(43) Pub. Date: Mar. 30, 2017

(54) Temperature Compensation of Fabricated Semiconductors

(71) Applicant: SANKEN ELECTRIC CO., LTD., Niiza-shi (JP)

(72) Inventors: Hironori Aoki, Asaka-shi (JP); Shuichi KANEKO, Yoshikawa-shi (JP)

(21) Appl. No.: 14/865,526

(22) Filed: Sep. 25, 2015

(51) Int. Cl. H01L 27/06; H01L 49/02; H01L 29/20

(52) U.S. Cl. CPC H01L 27/0629; H01L 29/2003; H01L 28/20

(57) ABSTRACT

Semiconductor devices and methods are described wherein temperature dependence of leakage current in at least one pathway of a device is compensated by a resistor in the device. Control of temperature dependent leakage current is particularly useful for silicon nitride devices and for circuits such as cascode circuits. A semiconductor leakage current that increases with temperature may be compensated by a fabricated resistor such as a boron doped polysilicon resistor that is electrically connected to compensate the leakage current in the pathway.

### FIELD OF THE INVENTION

This relates to semiconductor devices having fabricated resistors and more specifically to the use of resistors within semiconductors to compensate for changes in performance due to temperature.

### BACKGROUND

Semiconductor devices experience leakage current, which is a quantum phenomenon wherein mobile charge carriers (electrons or holes) tunnel through an insulating region or junction. Leakage increases exponentially as the thickness of the insulating region decreases. Tunneling can also occur across semiconductor junctions between heavily doped P-type and N-type semiconductors. Other than tunneling via the gate insulator or junctions, carriers can also leak between source and drain terminals of a Metal Oxide Semiconductor (MOS) transistor. This phenomenon is called subthreshold conduction. The primary source of leakage occurs inside semiconductor comprising the transistor, but electrons can also leak between the transistors' interconnects. Leakage increases power consumption and if sufficiently large can cause the circuit to fail specification.

Semiconductor leakage current is affected by temperature, with deleterious effects on circuits that employ the semiconductor. To some extent, every semiconductor and every semiconductor based circuit is affected by leakage current. Consequences of this include changes in bias voltages and changes in current flow of circuits that utilize semiconductors as active devices due to sneak circuit paths. This phenomenon causes many problems, such as limitation in operating conditions, and the need to design in flexibility for temperature variance. In many cases additional circuit components are added for such compensation.

A particularly temperature sensitive configuration that is often implemented in a fabricated semiconductor device is the cascode transistor configuration. FIG. 1 is a diagram of a cascode configuration. In this circuit normally-on FET 11 and a normally-off FET 12 are connected in a cascade. The combined transistor circuit operates as a normally-off transistor. The output of the configuration is taken based on resistor 13 as a load from terminal OUT 14 as shown in FIG. 1.

In a cascode configuration, the transistors Q1 and Q2 are connected in series as shown in FIG. 1. In this particular example, the gate of Q1 is connected to the source of Q2. Q1 injects current into the drain of Q2 at X (15). Q1 acts as a current buffer for Q2, provides mitigation of deleterious Miller effects within Q2, and provides an active load for Q2. The active load greatly increases the possible voltage gain of the gain cell without the need for large valued resistors.

In this example, a voltage of several hundred volts can be applied to the drain such as 600 volts In other words, the voltage stress at the drain of Q1 is 600 volts.

From this moment the voltage potential at X rises to the source voltage of Q1. Since the gate of Q1 is connected to the source of Q2, the gate of Q1 with respect to X (source of Q1) becomes negative. As the voltage potential at point X further increases, this negative voltage begins to exceed the threshold voltage of Q1. (example −5V) and Q1 is turned off. A high voltage develops at the drain in response to Q1. In this case, Q2 is not subjected to a large voltage. To reduce conduction loss Q2 is designed with as low a breakdown voltage as possible. For example, the breakdown voltage of Q2 may be about 20V.

In this example, when the leakage current of Q1 is large, the potential at point X where Q1 is turned off rises gradually. Holding the voltage potential at X at a high potential deteriorates the leakage current performance of Q2. Q2 cannot withstand a high potential, as stated in the previous paragraph. The temperature dependence of leakage current exacerbates this problem. As leakage current increases the voltage across the effected device increases.

### Attempts to Alleviate the Leakage Problem

The problem of high leakage current in the cascode circuit configuration shown in FIG. 1 has been addressed as shown in FIG. 2. In FIG. 2 resistor 26 (“R2”) is inserted between the source and drain of transistor 22 (“Q2”). This allows some compensation for the rise of leakage current due to the rise of voltage at point 25 (“X”) with respect to temperature rise.

The resistance of resistor 25 (“R2”) is selected in accordance with the leakage current of transistor 21 (“Q1”), and the voltage potential at the point X. For example if the leakage current of Q1 is 1 uA and the voltage of point X is 10V, then a 10 MΩ resistor value is an appropriate selection. Since leakage current is subject to manufacturing tolerance variations, R2 is set to accommodate a maximum value of expected leakage current due to worst-case temperature effects. In this case the resistance value would have to be decreased.

A second conventional attempt to solve this problem is shown in FIG. 3. Here, a clamping diode is inserted instead of a conductive resistor. This allows clamping the overvoltage to a set level. However, variations in the leakage current of the circuit shown in FIG. 3 can be large and in some instances a smaller resistance value may be required. In this case, when the leakage current is low, under a worst case scenario, the potential at point 35 (“X”) is not increased and cannot turn off transistor 31 (“Q1”). That is, in order to obtain a desired voltage potential at X, a certain amount of leakage current is needed. Accordingly, relying on the diode internal resistance to set the potential at point X does not actually stabilize the cascode. Furthermore, this approach to the problem incurs additional cost and size for the extra external components.

### Leakage Current Problems in Other Fabricated Semiconductors

Although cascode configurations can be particularly sensitive to an unstable leakage current, a wide variety of other semiconductor fabrications also suffer performance due to leakage current changing with temperature. A short list would include mirror circuits in op amps and precision amplifiers, and even diodes such as zener diodes, which have forward bias leakage currents that are particularly sensitive to temperature.

Current mirror subcircuits are an important element of many integrated circuits. In particular, they are used in operational amplifier circuits as current sources and sinks to bias amplification stages. The temperature sensitivity of the transistors that make up the current mirror sub-circuits result in increased output offset errors and variations in power supply current draw. This is especially problematic in precision operational amplifiers and instrumentation amplifiers, where even the slightest offsets greatly reduce circuit accuracy. The typical methods of dealing with output offset error are either to accept the increased offset error and use worst case design principles, or select an operational amplifier of greater accuracy, usually at higher cost.

Another method uses a chopper-stabilized operational amplifier, but this choice is less than ideal for circuits where chopper noise is a consideration. Still more complex techniques involve analog-to-digital conversion, processing and “zeroing” out the offset error due to leakage current, in software.

Current mirrors used in these chips can be classified into a number of different variations. A few such variations are known as the Wilson, Widlar and Gain-Boosted current mirrors. The Wilson and Widlar current mirrors are used extensively in integrated circuit design. One particular use is in operational amplifier integrated circuits to bias the various gain stages of an operational amplifier. Operational amplifiers are characterized by several performance metrics, such as power supply rejection ratio, common-mode rejection ratio, open-loop gain, and the common-mode gain of the differential input stage. Temperature instability of current mirrors adversely affects these critical performance parameters. This temperature sensitivity is due to the variability of leakage current in semiconductor devices due to varied device temperature.

Another important area of temperature dependence of leakage current with deleterious effects on device and circuit performance is in light emitting diodes. This is particularly important in opto-isolators where temperature effects on bias currents can directly affect quantitative performance. To compensate for the temperature induced variability of the bias current of the LED, designers often have to use worst-case design techniques, which increases complexity and cost.

Thus, a broad range of fabricated semiconductor devices are adversely affected by temperature effects on leakage current. Furthermore, increased power consumption due to increased temperature often prompts use of a power supply that has the capacity to accommodate the increased load. In a complex system consisting of many integrated circuits, the increase in power consumption due to temperature can be significant. This drives increase complexity and cost of the power supply and distribution system. Because of all these problems, any technique or device that can alleviate the temperature caused drift in bias leakage problem would provide immense benefits to this field.

### TABLE OF DRAWINGS

FIG. 1 is a diagram of a cascode that has two transistors.

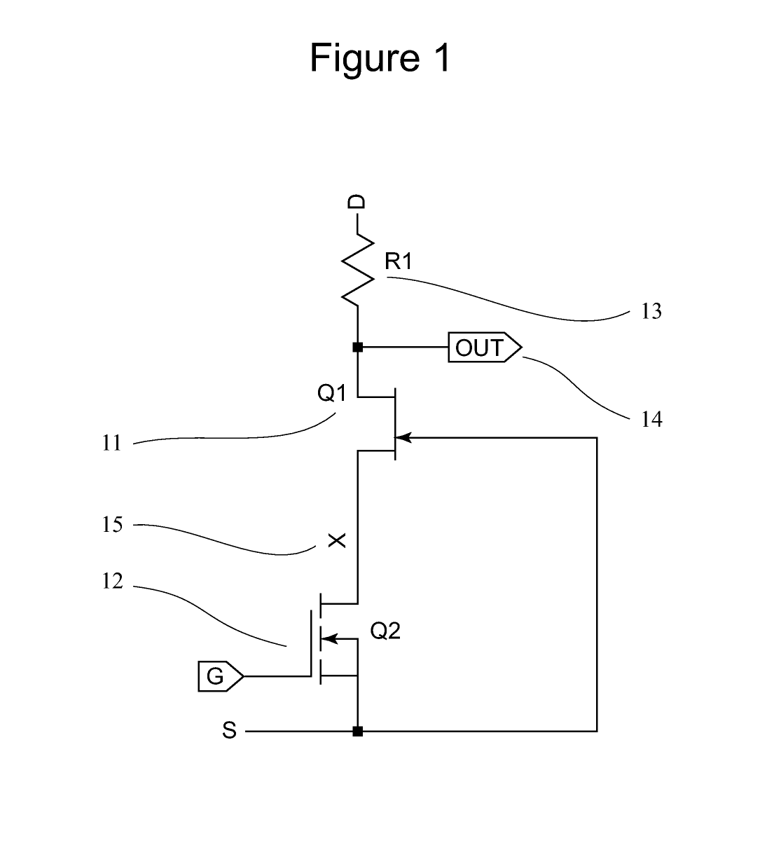

FIG. 2 is a cascode with a leak current compensating resistor added.

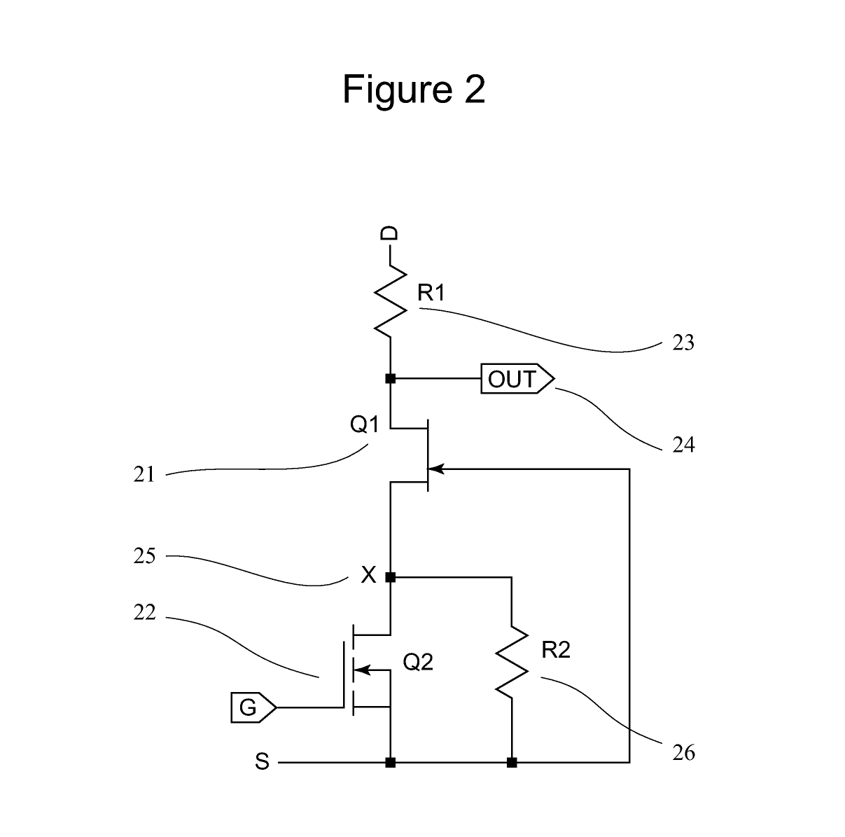

FIG. 3 is a cascode with a clipping diode added.

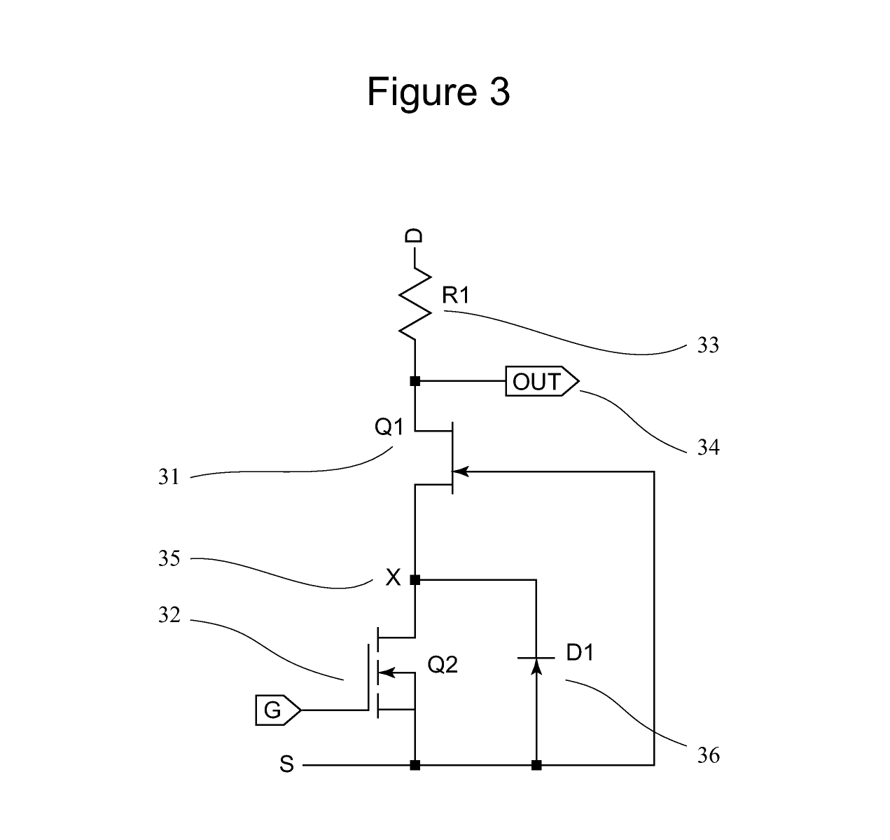

FIG. 4 is cascode fabricated in silicon according to an embodiment.

FIG. 5 is an outline of a fabricated semiconductor as an example of a mirror circuit embodiment.

### SUMMARY

Problems in the art outlined above are alleviated by embodiments of the invention. One embodiment is a fabricated semiconductor having temperature compensated leakage current in at least one pathway, comprising at least one semiconductor device in a pathway having a leakage current that increases with temperature and a fabricated resistor electrically connected to compensate the leakage current in the pathway. In an embodiment, the semiconductor device is a gallium nitride device and the leakage current is compensated by at least 50% within the operating region of the gallium nitride device. In an embodiment the fabricated resistor is polysilicon doped with at least one of boron, arsenic and phosphorus. In an embodiment the semiconductor device is a cascode comprising a first transistor connected in series with a second transistor wherein the gate of the first transistor is connected to the source of the second transistor. In an embodiment the resistor has a positive temperature coefficient of resistance and is connected to the source of the first transistor and compensates leakage current of the first transistor. In an embodiment the resistor is boron doped to have a positive temperature coefficient of resistance and accommodates at least one half of the semiconductor's increased leakage current with increased temperature.

In an embodiment the at least one semiconductor device comprises a mirror circuit and the resistor is connected to compensate at least 50% of the leakage current variation with temperature. In an embodiment the at least one semiconductor device participates in a timing circuit that is affected by the increase in leakage current with temperature and the fabricated resistor is connected to compensate at least 50% of the leakage current variation with temperature. In an embodiment the semiconductor device has at least one PN junction with improved temperature stability, comprising a positive temperature coefficient resistor in parallel with the at least one PN junction. In an embodiment the device comprises a light emitting diode of enhanced stability over the light emitting diode's operating temperature range. In an embodiment the resistor comprises polysilicon that is highly doped with boron and has a positive temperature coefficient of resistance, and wherein the resistor is in series with the light emitting diode. In an embodiment the fabricated semiconductor comprises a gallium nitride based cascode of two transistors and wherein the resistor is doped with boron and connected in parallel with a source to the drain of one transistor and in series with the source to drain of the other transistor. In an embodiment the pathway comprises a mirror circuit within the semiconductor.

In an embodiment the semiconductor device comprises a cascode of two transistors connected in series, and a polysilicon resistor between the source and drain of the second transistor wherein the polysilicon resistor has a positive temperature coefficient. In an embodiment the semiconductor device comprises a mirror circuit configuration with one or more temperature compensated PN junction leakage currents, comprising a polysilicon resistor across one or more PN junctions wherein the polysilicon resistor has a positive temperature coefficient. In an embodiment the polysilicon resistor has a positive temperature coefficient that is between 50% and 100% of the absolute value of the temperature coefficient of leakage current of one or more PN junctions. In an embodiment the absolute value of the positive temperature coefficient is between 50 to 100 percent of the absolute value of the respective negative temperature coefficient of the PN junction leakage current.

An embodiment provides a method of fabricating a CMOS semiconductor comprising multiple field effect transistors and having a temperature compensated leakage current within a selected field effect transistor, wherein a gate oxide deposition step comprises depositing silicon oxide over a region that is contiguous with a drain electrode and a corresponding source electrode of the selected field effect transistor to form an insulating layer therebetween; and then during a subsequent gate polysilicon deposition step: depositing polysilicon on the deposited silicon oxide over the region that is continuous with the drain electrode and the source electrode; and subsequently injecting boron selectively into the polysilicon in the region that is continuous with the drain electrode and the source electrode, thereby forming a conductive polysilicon path between the drain electrode and the source electrode of the selected field effect transistor. In an embodiment of the method, a sufficiently high level of boron is injected to create a resistor having positive temperature coefficient of resistance and wherein the selected field effect transistor participates in a cascode circuit configuration. Other embodiments will be appreciated upon reading this disclosure.

Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

### DETAILED DESCRIPTION OF THE EMBODIMENTS

The problems in the field cited above are addressed successfully by fabricating a temperature sensitive resistor within the semiconductor device as a mutually fabricated part. In this way, the resistor can share the same physical medium and quickly respond to the same temperature changes as the semiconductor device. Moreover, this saves space from having to use an exterior component such as an exterior resistor to alleviate the change in leakage current with temperature. This also saves cost from having to employ a separate resistor or other component. The resistor is fabricated to have a specific resistance and a specific temperature coefficient that compensates for at least some of the temperature dependence of leakage for the semiconductor device.

In an embodiment the resistor has a positive temperature coefficient and increases resistance (with decreasing current flow through the resistor) to compensate an increasing leakage current of the semiconductor device. In an embodiment the resistor has a negative temperature coefficient and increases resistance (with increasing current flow through the resistor) to compensate an increasing leakage current of the semiconductor device. The selection of positive or negative coefficient is determined by the circuit configuration and paths in the semiconductor device. For example, when connected in parallel with a semiconductor device junction or other connection circuit path that has a positive temperature coefficient of leakage current, the resistor should have a positive temperature coefficient of resistance (causing negative temperature coefficient of resulting current flow through the resister), and vice versa.

Preferably at least 25% of the temperature dependence is compensated this way over at least a 50 degree centigrade temperature range. More preferably at least 35% and yet more preferably at least 50% of the temperature dependence of the semiconductor device leakage current is compensated over at least a 50 degree centigrade temperature range. In an embodiment at least 75% of the temperature dependence of the semiconductor device leakage current is compensated over a 50 degree centigrade temperature range. In an most preferred embodiment at least 90% of the temperature dependence of the semiconductor device leakage current is compensated over a 50 degree centigrade temperature range. Preferably in an embodiment, the 50 degree performance range specified is measured from 20 degrees to 70 degrees centigrade.

A variety of techniques may be used to stabilize, but not necessarily eliminate, the semiconductor leakage and are discussed further. By incorporating a “resistor” (typically an extra conduction path with its own temperature sensitive conductivity) in parallel with the semiconductor device, additional current will be drawn from the voltage source. However, if the resistor's temperature coefficient of resistance causes a current flow that is equal and opposite to that of the semiconductor device, then as the semiconductor device conducts greater leakage current due to temperature, the resistor will conduct less. This action will tend to fix the leakage current to a stable range, despite large changes in device temperature.

Preferably the resistor is built as a semiconductor material such as doped polysilicon or other added conductive material such as tungston to the semiconductor device. The critical transistor device(s) (which can be individual transistors or entire regions of connected transistors) having leakage issues within a fabricated semiconductor can be augmented with this resistor. By choosing the resistor carefully, the device leakage current can be offset at least partially and made more stable to temperature change. This has great value in improving the critical performance parameters of the device, be it a cascode device, a mirror current section in an operational amplifier, or other device.

### Resistor Fabrication

In desirable embodiments, one or more resistors are made on the same semiconductor substrate as the compensated semiconductor device.

Preferably the resistor comprises polysilicon doped with one or more of boron, phosphorous or arsenic. In another embodiment the resistor is made from tungsten. Examples of the latter are provided in U.S. No. 20150227158, the contents of which, and particularly details of fabricating and using polysilicon and tungsten resistors are particularly incorporated by reference in their entireties. Preferred embodiments use boron doped polysilicon, which is more easily integrated into existing manufacturing processes. For example, polysilicon can be vapor deposited in a same step with formation of gate electrodes of MOSFETs on the same chip. However, other embodiments can use separate resistor fabrication steps, which optionally can be merged with electrode fabrication, via materials and methods described in U.S. Pat. No. 8,334,187, US application No. 20090023263, US application No. 20150171077, and US application No. 20100259315, the contents of which, and particularly details of fabricating and using resistors within fabricated semiconductors are particularly incorporated by reference in their entireties. Further details of using boron can be found in” “Effect of Boron and BF 2+Implant on Polysilicon Resistors J. Electrochem. Soc. 2002 149(4): G271-G275” and in the publications referenced therein.

### Polysilicon is Preferred

Polysilicon is preferred for making resistors according to embodiments because such silicon based components can be made as part of the chip fabrication process. For example, polysilicon film can be deposited by the sputtering or the LPCVD technique, but to get a good conformal film and in-situ poly doping, the LPCVD technique is preferred. A general polysilicon film deposition can be carried out for example in the LPCVD reactor at around 5 mTorr pressure and the deposition temperature ranges from 600 to 650 degrees Centigrade. Generally the SiH4 precursor is used for the polysilicon film deposition and can be diluted for example by 20 to 30% with added nitrogen gas.

Generally these operations include, but are not limited to, layering, doping, heat treatments, and patterning. In one embodiment the resistance of respective impurity diffusion layers is controlled by selectively determining the width, length, contact depth, type of impurity, and doping concentration for the impurity. The resistance of the resulting resistor may further be controlled by the selective incorporation of respective metal patterns connecting the impurity diffusion layers. This, allows control of diffusion resistance for the one or more impurity diffusion layers and the contact resistance provided by one or more metal patterns within a series of impurity diffusion layers.

In an embodiment resistors are formed from a doped polysilicon layer or from a region of a semiconductor substrate containing diffused impurities. A device isolation layer may be formed on a semiconductor substrate to thereby define an active region. A resistor then may be formed on the device isolation layer from a patterned polysilicon layer having a predetermined length, thickness, and width. Alternatively, the resistor may be formed from an impurity diffusion layer having a predetermined doping concentration, diffusion depth and width, within the active region. Electrodes may be connected to opposite ends of the polysilicon pattern and impurity diffusion layer, respectively. However, preferably the polysilicon resistor directly contacts an active semiconductor region such as a gate, drain or source of a transistor.

Layering is the operation used to add layers of a selected thickness to a wafer substrate. These layers can be insulators, semiconductors, conductors, and the like and can be grown or deposited by a number of suitable methods (e.g., chemical vapor deposition, sputtering, and the like). Doping is the process that introduces specific amounts of dopants in the wafer surface through openings in the surface layers. Typical technique used for doping is, e.g. ion implantation. Doping is used, for example, to create active regions in transistors or to created resistivity regions in resistors. Heat treatments are operations in which a complete wafer or a portion of a wafer is heated and hold at a predefined temperature (range) for some predetermined time to achieve specific results. A common heat treatment is called an annealing which is typically employed to repair defects in crystal structures introduced by ion implantation. Patterning is the operation that employs a series of steps that result in the removal of selected portions of added surface layers. The series of steps includes first forming a layer of resist or photoresist over a polysilicon resistor device. Then a resist mask is aligned with the device. Subsequently, the layer of resist is exposed or irradiated through the resist mask, which selects portions of layer of resist that are later removed to expose underlying portions of the device. Continuing, a fabrication process, such as ion implantation, ion diffusion, and the like is performed on exposed portions of the device.

The prevalent processes for producing a high-ohm polysilicon resistor typically include: depositing an undoped polysilicon layer over an insulating layer of a silicon substrate, the undoped polysilicon layer is typically in a thickness range of 200 nm to 400 nm; then implanting dopant atoms such as boron into the polysilicon layer with a subsequent annealing step, which defines the resistance of the polysilicon resistor.

In an embodiment, first dopant atoms including deep energy level donors may be implanted into at least a portion of a polysilicon layer. Such deep energy donors can be for example, selenium atoms, sulfur atoms or nitrogen atoms.

In an embodiment, second dopant atoms may be implanted into at least a portion of the polysilicon layer. The second dopant atoms can differ from the first dopant atoms. The second dopant atoms may be have a shallow energy level (also referred as shallow donors). Such shallow donors may exhibit a small difference between an energy level of the doping atoms and the conduction band edge; for example, a difference smaller than 100 meV, In one or more embodiments, the second dopant atoms may include boron atoms phosphorous atoms or arsenic atoms. The second dopant atoms may be implanted before, during or after implanting the first dopant atoms.

An annealing process may be carried out after the first and second dopant atoms have been implanted into the polysilicon layer.

Devices that Employ the Temperature Compensation Resistor(s)

### Cascode Device Example

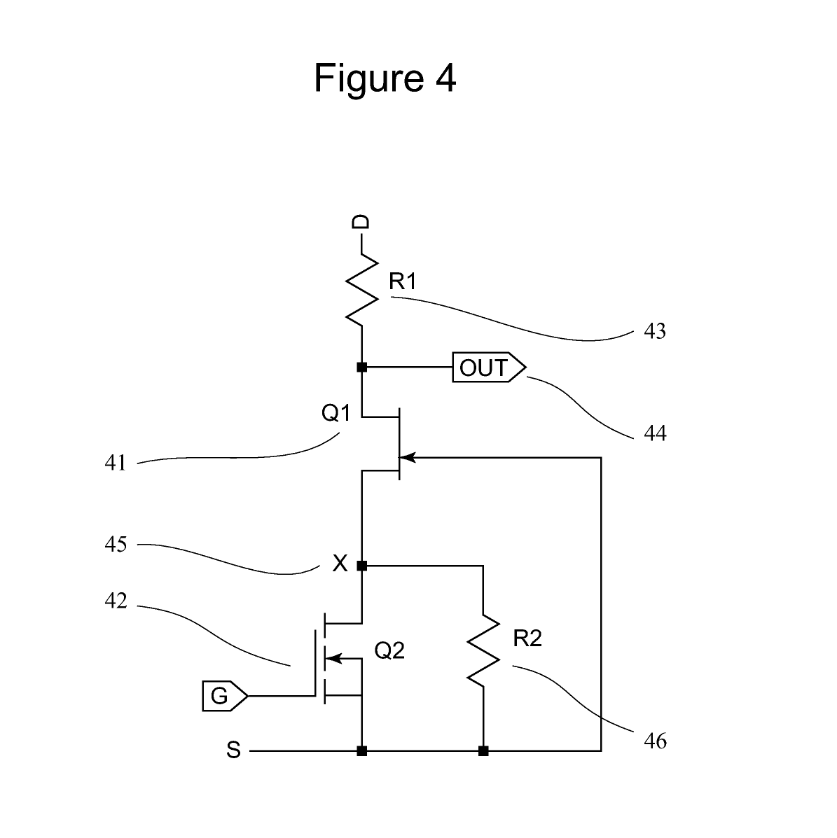

See FIG. 4. This circuit, which is fabricated on a chip has a resistor 46 (“R2”) on the same chip as and connected to transistor 42 (“Q2”) as shown. Resistor 46 is formed of polysilicon. Leakage current has a positive coefficient, which increases as the temperature is higher. Resistance value of the poly-silicon resistor 46 is adjusted by implanting boron. Temperature coefficient changes from negative to positive by the injection amount of boron. Boron may be added to a high enough level to adjust the temperature coefficient of resistor to counteract at least 50% of the leakage current of R2 (in this example) over a temperature range of 20 to 70 degrees centigrade. The resistance of the formed polysilicon resistor 46 for a given temperature preferably is adjusted by changing the thickness, depth and/or length of the polysilicon, although the amount of boron also can be controlled in conjunction with dimensions, as a skilled artisan will appreciate. Preferably the temperature coefficient is controlled by adjusting the implanted boron concentration as is known in the art, Other atoms such as phosphorous or arsenic may be also implanted or added during a vapor phase formation step.

### Wide Applicability

The strategy of adding polysilicon with high boron levels to make a positive temperature coefficient resistor connected to one or more transistors during chip fabrication can be used in many embodiments. A wide variety of cascode circuit configurations and semiconductor fabrications thereof can benefit. A very small sample is provided here.

See for example US No. 20130320354, which describes a cascode circuit of a normally-on transistor in a first semiconductor die and a normally-off transistor within a second semiconductor die wherein a normally-off semiconductor switch may include beneficial electrical properties of the normally-on transistor such as low-on resistance or high-reverse blocking capabilities+a semiconductor switch including a cascode circuit of a normally-off transistor in a first semiconductor die and a normally-on transistor, a gate resistor and a voltage clamping element in a second semiconductor die, respectively. a normally-off semiconductor switch including a cascode circuit of a normally-off transistor and a normally-on transistor. As an example, the normally-on transistor may be any one of Junction Field Effect Transistor (JFET), Metal Insulator Semiconductor Field Effect Transistor (MISFET) such as a Metal Oxide Semiconductor Field Effect Transistor (MOSFET) and derivatives such as Double-diffused MOSFET (DMOSFET), High Electron Mobility Transistor (HEMT) or any transistor including a gate configured to control the conductivity between source and drain by voltage application.

The normally-off transistor may also be any one of Junction Field Effect Transistor (JFET), Metal Insulator Semiconductor Field Effect Transistor (MISFET) such as a Metal Oxide Semiconductor Field Effect Transistor (MOSFET) and derivatives such as Double-diffused MOSFET (DMOSFET), High Electron Mobility Transistor (HEMT) or any transistor including a gate configured to control the conductivity between source and drain by voltage application. The normally-off transistor is formed within a first semiconductor die in this example. The normally-on transistor is formed within a second semiconductor die and includes a plurality of transistor cells. A skilled artisan can add a polysilicon resistor having positive temperature effects to the second semiconductor die to compensate leakage current changes with temperature.

A particularly desirable application of the polysilicon resistor with positive temperature dependence is for GaN power transistors. Basic GaN power semiconductors are depletion mode (normally on) devices. Cascoding high voltage GaN switches with low-voltage MOSFETs is a recent development that combines the advantages of silicon with GaN power devices. A summary of this application can be found in US No. 20140027785. The contents of this reference and particularly details of device and circuit construction are specifically incorporated by reference.

A particularly good example of combining a main power transistor and a cascode MOSFET into an integrated circuit is provided in US No. 20140146428. This reference summarizes the approach of mating newly available GaN and SiC power semiconductors with in a cascode circuit with a normally off silicon MOSFET and attendant problems of temperature dependent bias currents. A polysilicon (or tungsten) resistor as described herein profitably can be used in these kinds of switches generally by building them into the semiconductor substrate, thereby reducing outboard component space requirements and cost. The contents of this reference and particularly details of device fabrication and circuit construction are specifically incorporated by reference.

### Mirror Circuit-Element Example

The same materials and fabrication techniques taught, referred to and referenced specifically herein may be used for alleviating temperature induced bias effects in other fabricated devices. In particular, mirror circuits found in operational amplifiers and other amplifiers have input bias currents that change with temperature. Such bias current errors can be corrected by at least 50%, 75%, 90% or more by careful addition of a polysilicon resistor with positive temperature coefficient. The use of polysilicon, which can be applied in an existing or modified step of an existing fabrication procedure, combined with a specific controlled boron injection can provide such benefits without greatly increasing costs.

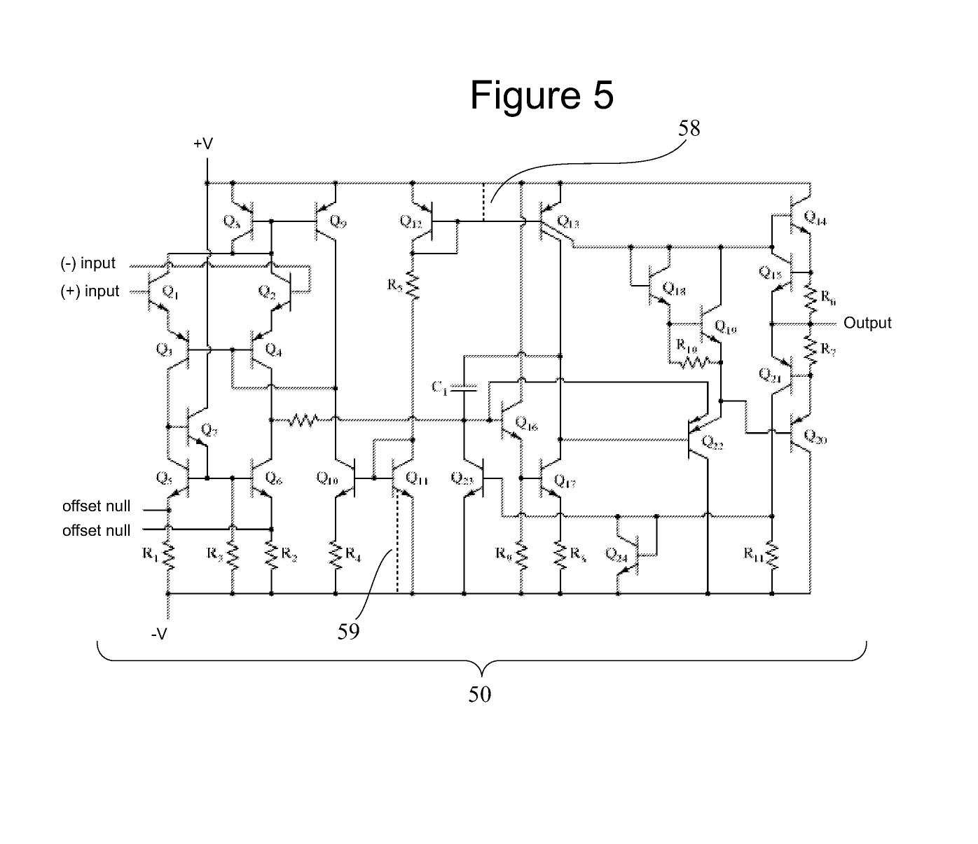

FIG. 5 shows a standard 741 operational amplifier transistor and resistor chip fabrication configuration 50. A mirror circuit is used here in the input section. In an embodiment polysilicon resistors 58 and 59 with positive temperature coefficient are added to counteract at least 50% of the input bias current. Adding such additional conductors 58 and 59 increase the total bias current, but decrease the sensitivity to temperature, which is an important quality improvement for an amplifier working in differential mode.

The 741 fabrication is provided as an example. Virtually every fabricated chip circuit having a mirror circuit can benefit from this embodiment. A skilled artisan reader can readily apply the materials and methods detailed, referred to and specifically referenced herein to such other fabrications to improve their temperature response. Such wide variety of configurations are intended as embodiments of the invention.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

1. A fabricated semiconductor having temperature compensated leakage current in at least one pathway, comprising:
at least one semiconductor device in a pathway having a leakage current that increases with temperature; and
a fabricated resistor electrically connected to the at least one semiconductor device, the fabricated resistor fabricated so as to have a temperature coefficient of resistance that causes a current flow in the fabricated resistor that is equal and opposite to that of the at least one semiconductor device to compensate the leakage current in the pathway.

2. The fabricated semiconductor of claim 1, wherein
the at least one semiconductor device is a gallium nitride device, and
the fabricated resistor is fabricated such that the leakage current is compensated by at least 50% within an operating region of the gallium nitride device.

3. The fabricated semiconductor of claim 1, wherein the fabricated resistor is fabricated such that the fabricated resistor is polysilicon doped with at least one of boron, arsenic and phosphorous.

4. The fabricated semiconductor of claim 1, wherein the at least one semiconductor device is a cascode comprising a first transistor connected in series with a second transistor wherein the gate of the first transistor is connected to the source of the second transistor.

5. The fabricated semiconductor of claim 4, wherein the fabricated resistor has a positive temperature coefficient of resistance and is connected to the source of the first transistor and compensates leakage current of the first transistor.

6. The fabricated semiconductor of claim 1, wherein the fabricated resistor is fabricated such that the fabricated resistor is boron doped to have a positive temperature coefficient of resistance and accommodates at least one half of the increased leakage current of the at least one semiconductor device with increased temperature.

7. The fabricated semiconductor of claim 1, wherein the at least one semiconductor device comprises a mirror circuit and the fabricated resistor is connected to compensate at least 50% of the increased leakage current variation with temperature.

8-11. (canceled)

12. The fabricated semiconductor of claim 5, wherein the cascode comprises a gallium nitride based cascode of the first and the second transistors and wherein the fabricated resistor is doped with boron and connected in parallel with a source to the drain of one transistor of the first and second transistors and in series with the source to drain of the other transistor of the first and second transistors.

13. The fabricated semiconductor of claim 6, wherein the pathway comprises a mirror circuit within the fabricated semiconductor.

14. The semiconductor device of claim 1, wherein the at least one semiconductor device comprises a cascode of a first transistor and a second transistor connected in series, and wherein the fabricated resistor comprises a polysilicon resistor between the source and drain of the second transistor wherein the polysilicon resistor has a positive temperature coefficient.

15. The semiconductor device of claim 1, comprising a mirror circuit configuration with one or more temperature compensated PN junction leakage currents, comprising a polysilicon resistor across one or more PN junctions wherein the polysilicon resistor has a positive temperature coefficient.

16. The semiconductor device of claim 5, wherein the fabricated resistor comprises a polysilicon resistor having a positive temperature coefficient that is between 50% and 100% of the absolute value of the temperature coefficient of leakage current.

17. The semiconductor device of claim 5, wherein the absolute value of the positive temperature coefficient is between 50% to 100% of the absolute value of a negative temperature coefficient of the leakage current.

18. A method of fabricating a CMOS semiconductor comprising multiple field effect transistors and having a temperature compensated leakage current within a selected field effect transistor, wherein:
a gate oxide deposition step comprises:
depositing silicon oxide over a region that is contiguous with a drain electrode and a corresponding source electrode of the selected field effect transistor to form an insulating layer therebetween; and then
during a subsequent gate polysilicon deposition step:
depositing polysilicon on the deposited silicon oxide over the region that is continuous with the drain electrode and the source electrode; and subsequently injecting boron selectively into the polysilicon in the region that is continuous with the drain electrode and the source electrode, thereby forming a conductive polysilicon path between the drain electrode and the source electrode of the selected field effect transistor.

19. The method of claim 18 wherein a sufficiently high level of boron is injected to create a resistor having positive temperature coefficient of resistance and wherein the selected field effect transistor participates in a cascode circuit configuration.
